(19) United States
(12) Patent Application Publication
(10) Pub. No.: US 2025/0293125 A1
(43) Pub. Date: Sep. 18, 2025

(54) SEMICONDUCTOR DEVICE

(71) Applicants: KABUSHIKI KAISHA TOSHIBA, Tokyo (JP); TOSHIBA ELECTRONIC DEVICES & STORAGE CORPORATION, Tokyo (JP)

(72) Inventors: Hibiki OTSU, Kawasaki (JP); Kazuhiro INOUE, Kitakyushu (JP)

(73) Assignees: KABUSHIKI KAISHA TOSHIBA, Tokyo (JP); TOSHIBA ELECTRONIC DEVICES & STORAGE CORPORATION, Tokyo (JP)

(21) Appl. No.: 18/826,401

(22) Filed: Sep. 6, 2024

(30) Foreign Application Priority Data
Mar. 15, 2024 (JP) 2024-041538

(51) Int. Cl. H01L 23/495; H01L 23/31; H01L 25/16; H01L 31/167

(52) U.S. Cl. CPC H01L 23/49537; H01L 23/3142; H01L 23/49555; H01L 23/49575; H01L 25/167; H10F 55/25

(57) ABSTRACT

According to one embodiment, a semiconductor device includes: a first transistor; a light receiving element that is in contact with the first transistor in a first direction, with a light receiving surface of the light receiving element being provided to face in the first direction; a light emitting element including a radiation surface that is provided to face the light receiving surface of the light receiving element in the first direction; and a first resin member that seals the first transistor, the light receiving element and the light emitting element, and has light transmissivity, wherein a vertex of a surface that is in contact with the first transistor in the light receiving element is provided at a position that does not overlap the first transistor in the first direction.

### CROSS-REFERENCE TO RELATED APPLICATION

This application is based upon and claims the benefit of priority from prior Japanese Patent Application No. 2024-041538, filed Mar. 15, 2024, the entire contents of which are incorporated herein by reference.

### FIELD

Embodiments described herein relate generally to a semiconductor device.

### BACKGROUND

As a semiconductor device, a photo relay device is known. The photo relay device is a device of a semiconductor relay including a light emitting element and a light receiving element. The photo relay device is a contactless relay, and is used for transmission of various signals.

### BRIEF DESCRIPTION OF THE DRAWINGS

FIG. 1 is a perspective view illustrating an example of an external structure of a photo relay device according to a first embodiment.

FIG. 2 is a cross-sectional view illustrating an example of an internal structure of the photo relay device according to the first embodiment.

FIG. 3 is a plan view illustrating an example of a planar layout of various elements included in the photo relay device according to the first embodiment.

FIG. 4 is a cross-sectional view along line IV-IV in FIG. 3, illustrating an example of an internal structure of the photo relay device according to the first embodiment.

FIG. 5 is a circuit diagram illustrating an example of a circuit configuration of the photo relay device according to the first embodiment.

FIG. 6 is a diagram illustrating a stress influence in the photo relay device according to the first embodiment.

FIG. 7 is a cross-sectional view illustrating an example of an internal structure of a photo relay device according to a second embodiment.

FIG. 8 is a diagram illustrating an example of a dicing step of a light receiving element in the process of manufacturing the photo relay device according to the second embodiment.

FIG. 9 is a cross-sectional view illustrating an example of an internal structure of a photo relay device according to a third embodiment.

FIG. 10 is a diagram illustrating an example of a dicing step of a light receiving element in the process of manufacturing the photo relay device according to the third embodiment.

### DETAILED DESCRIPTION

In general, according to one embodiment, a semiconductor device includes: a first transistor; a light receiving element that is in contact with the first transistor in a first direction, with a light receiving surface of the light receiving element being provided to face in the first direction; a light emitting element including a radiation surface that is provided to face the light receiving surface of the light receiving element in the first direction; and a first resin member that seals the first transistor, the light receiving element and the light emitting element, and has light transmissivity, wherein a vertex of a surface that is in contact with the first transistor in the light receiving element is provided at a position that does not overlap the first transistor in the first direction.

Hereinafter, embodiments are described with reference to the accompanying drawings. In the description below, structural elements having substantially identical functions and structures are denoted by an identical reference sign. In a case where elements having similar structures are particularly distinguished, there is a case in which mutually different characters or numerals are added to the end of an identical reference sign.

In the description below, an expression that a certain first element is “connected” to another second element includes a mode in which the first element is indirectly connected to the second element via an intermediate element that is always or selectively rendered conductive, or is directly connected to the second element without via the intermediate element.

### 1. First Embodiment

1.1. Entire Structure

A first embodiment is described. In the present embodiment, a photo relay device is described as an example of a semiconductor device.

FIG. 1 is a perspective view illustrating an example of an external structure of the photo relay device according to the first embodiment. As illustrated in FIG. 1, a photo relay device 1 includes such a structure that lead frames 10a, 10b, 20a and 20b extend from a housing structure that is sealed by a first resin member 80.

The lead frames 10a, 10b, 20a and 20b include, for example, gold-plated copper plates. The lead frames 10a and 10b, and the lead frames 20a and 20b, extend in mutually opposite directions in such a manner that the first resin member 80 is interposed therebetween. In the description below, a direction of extension of the lead frames 20a and 20b from the first resin member 80 is defined as “X direction”. A direction in which the lead frames 20a and 20b are arranged side by side is defined as “Y direction”.

End portions of the lead frames 10a and 10b function as input terminals 11a and 11b of the photo relay device 1. The input terminals 11a and 11b are connected to, for example, an external power supply, and receive various signals.

End portions of the lead frames 20a and 20b function as output terminals 21a and 21b of the photo relay device 1. The output terminals 21a and 21b are connected to, for example, an external device, and transmit various signals.

The first resin member 80 includes, for example, an epoxy resin including a shielding material such as carbon or silica. The first resin member 80 is provided in such a manner as to cover the photo relay device 1, excluding parts of the lead frames 10a, 10b, 20a and 20b. The first resin member 80 protects the structural elements of the photo relay device 1 from physical disturbance. In addition, the first resin member 80 has a light shielding property. The first resin member 80 shields the photo relay device 1 from external light, and also blocks leakage of radiation light occurring in the inside of the photo relay device 1.

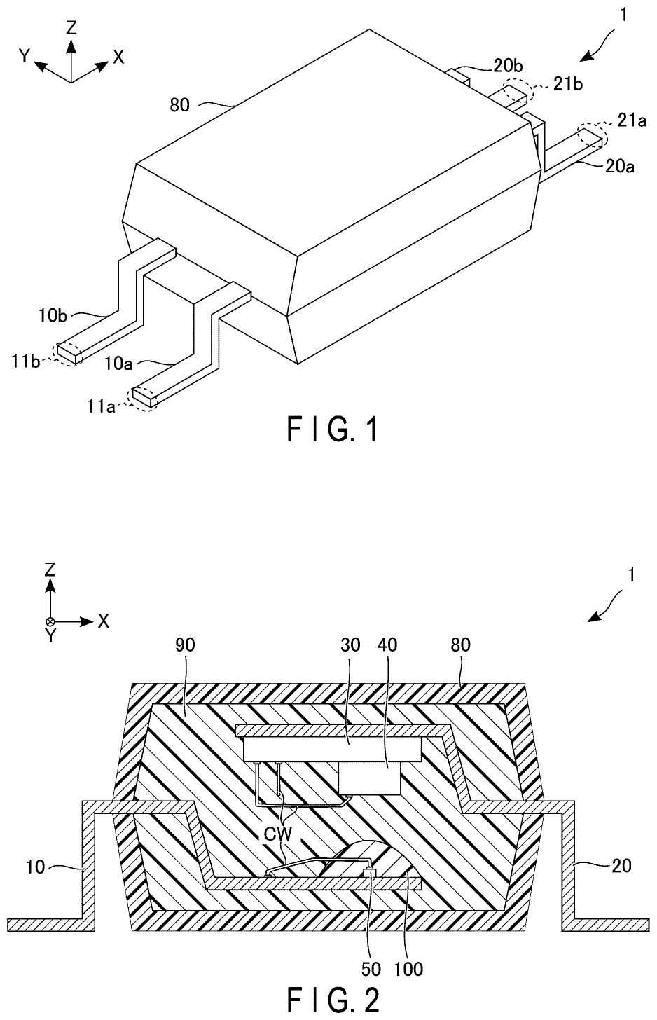

FIG. 2 is a cross-sectional view illustrating an example of an internal structure of the photo relay device 1 according to the first embodiment. As illustrated in FIG. 2, the photo relay device 1 includes a transistor 30, a light receiving element 40, a light emitting element 50, a second resin member 90, a third resin member 100, and a plurality of wires CW.

A lead frame 10 includes the lead frames 10a and 10b. In the description below, there is a case where the lead frames 10a and 10b are not distinguished and are described as the lead frame 10.

A lead frame 20 includes the lead frames 20a and 20b. In the description below, there is a case where the lead frames 20a and 20b are not distinguished and are described as the lead frame 20.

Those portions of the lead frames 10 and 20, which are sealed by the first resin member 80, are disposed to be arranged in a direction perpendicular to the X direction and Y direction. In the description below, a direction toward the lead frame 20, as viewed from the lead frame 10, is defined as “Z direction” or “upward direction”. A direction toward the lead frame 10, as viewed from the lead frame 20, is defined as “-Z direction” or “downward direction”.

That portion of the lead frame 10, which is sealed by the first resin member 80, extends in the X direction from that portion of the lead frame 10, which extends to the outside of the first resin member 80. That portion of the lead frame 20, which is sealed by the first resin member 80, extends in a direction opposite to the X direction from that portion of the lead frame 20, which extends to the outside of the first resin member 80.

The transistor 30 is, for example, an enhancement-type n-channel MOSFET (Metal Oxide Semiconductor Field Effect Transistor). The transistor 30 is provided in contact with a lower surface of the lead frame 20. The transistor 30 has, for example, such a configuration that circuitry is provided on a surface of an element.

The light receiving element 40 is, for example, a PDA (Photo Diode Array) or a phototransistor. Hereinafter, a case is described in which the light receiving element 40 is the PDA. The light receiving element 40 has a rectangular shape. The light receiving element 40 has, for example, such a configuration that circuitry is provided on a surface of an element. The light receiving element 40 is provided on a lower surface of the transistor 30. A light receiving surface is provided on a lower surface of the light receiving element 40. Specifically, the light receiving surface of the light receiving element 40 faces a side (downward side) on which the lead frame 10 is disposed.

The light emitting element 50 is, for example, an LED (Light Emitting Diode). The light emitting element 50 is provided on an upper surface of the lead frame 10. A radiation surface is provided on an upper surface of the light emitting element 50. Specifically, the radiation surface of the light emitting element 50 faces a side (upward side) on which the lead frame 20 is disposed. The radiation surface of the light emitting element 50 is opposed to the light receiving surface of the light receiving element 40 in the Z direction.

The second resin member 90 is, for example, an epoxy resin. The second resin member 90 is provided in the inside of the first resin member 80. The second resin member 90 includes a portion that is interposed between the light receiving element 40 and the light emitting element 50. The second resin member 90 covers portions of the lead frames 10 and 20, the transistor 30, the light receiving element 40, the light emitting element 50 and the wires CW, fixes the positions of the respective elements, and makes insulation between the elements. The second resin member 90 has light transmissivity.

The third resin member 100 is, for example, silicone. The third resin member 100 is provided on the lead frame 10 in the inside of the second resin member 90 in such a manner as to cover the light emitting element 50. The third resin member 100 fixes the position of the light emitting element 50, and protects the light emitting element 50 from physical or electrical disturbance. The third resin member 100 has light transmissivity.

The wires CW are, for example, bonding wires. The wires CW electrically connect the respective structural elements.
1.2. Planar Layout

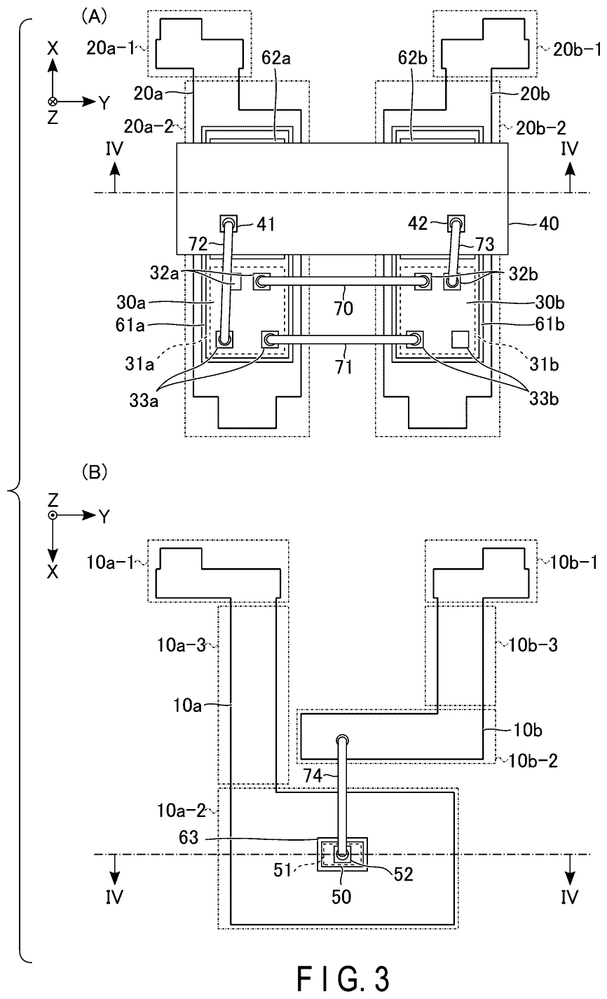

A planar layout of the photo relay device according to the first embodiment is illustrated by using FIG. 3. FIG. 3 is a plan view illustrating an example of a planar layout of various elements included in the photo relay device according to the first embodiment. Part (A) of FIG. 3 corresponds to a planar layout of the lead frames 20a and 20b, transistor 30 and light receiving element 40, in a case where the photo relay device 1 is viewed in the upward direction. Part (B) of FIG. 3 corresponds to a planar layout of the lead frames 10a and 10b and light emitting element 50, in a case where the photo relay device 1 is viewed in the downward direction. Note that in FIG. 3, the depiction of the first resin member 80, second resin member 90 and third resin member 100 is omitted. As illustrated in FIG. 3, the photo relay device 1 further includes adhesive layers 61a, 61b, 62a, 62b and 63. The transistor 30 includes transistors 30a and 30b. The wires CW include wires 70, 71, 72, 73 and 74.

As illustrated in part (A) of FIG. 3, the lead frames 20a and 20b include first portions 20a-1 and 20b-1 that extend to the outside of the first resin member 80 and include end portions functioning as the output terminals 21a and 21b; and second portions 20a-2 and 20b-2 extending in the X direction. The first portion 20a-1 of the lead frame 20a and the first portion 20b-1 of the lead frame 20b are provided side by side in the Y direction in the named order. The second portion 20a-2 of the lead frame 20a and the second portion 20b-2 of the lead frame 20b are provided side by side in the Y direction in the named order. The second portion 20a-2 of the lead frame 20a is, at one end thereof, put in contact with the first portion 20a-1 of the lead frame 20a. The second portion 20b-2 of the lead frame 20b is, at one end thereof, put in contact with the first portion 20b-1 of the lead frame 20b.

The transistors 30a and 30b have, for example, substantially identical configurations and shapes. The transistors 30a and 30b are provided side by side at positions that overlap, as viewed in the Y direction.

The transistor 30a is provided on a lower surface of the second portion 20a-2 of the lead frame 20a via the adhesive layer 61a. The transistor 30a includes electrodes 31a, 32a and 33a.

The electrode 31a is provided on an upper surface of the transistor 30a, and is in contact with the adhesive layer 61a. The electrode 31a functions as a drain terminal of the transistor 30a.

The electrodes 32a are provided on a lower surface of the transistor 30a. In the example illustrated in FIG. 3, two electrodes 32a are arranged side by side in the Y direction, but the two electrodes 32a are connected in the inside of the transistor 30a. Note that the arrangement of the electrodes 32a is not limited to the configuration and arrangement illustrated in FIG. 3. For example, the electrodes 32a may be a single electrode having a rectangular shape extending in the Y direction. The electrodes 32a function as a source terminal of the transistor 30a.

The electrodes 33a are provided on the lower surface of the transistor 30a. As viewed from the electrodes 32a, the electrodes 33a are provided at positions in an opposite direction to the X direction. In the example illustrated in FIG. 3, two electrodes 33a are arranged side by side in the Y direction, but the two electrodes 33a are connected in the inside of the transistor 30a. Note that the arrangement of the electrodes 33a is not limited to the configuration and arrangement illustrated in FIG. 3. For example, the electrodes 33a may be a single electrode having a rectangular shape extending in the Y direction. The electrodes 33a function as a gate terminal of the transistor 30a.

The transistor 30b is provided on a lower surface of the second portion 20b-2 of the lead frame 20b via the adhesive layer 61b. The transistor 30b includes electrodes 31b, 32b and 33b.

The electrode 31b is provided on an upper surface of the transistor 30b, and is in contact with the adhesive layer 61b. The electrode 31b functions as a drain terminal of the transistor 30b.

The electrodes 32b are provided on a lower surface of the transistor 30b. In the example illustrated in FIG. 3, two electrodes 32b are arranged side by side in the Y direction, but the two electrodes 32b are connected in the inside of the transistor 30b. Note that the arrangement of the electrodes 32b is not limited to the configuration and arrangement illustrated in FIG. 3. For example, the electrodes 32b may be a single electrode having a rectangular shape extending in the Y direction. The electrodes 32b function as a source terminal of the transistor 30b.

The electrodes 33b are provided on the lower surface of the transistor 30b. As viewed from the electrodes 32b, the electrodes 33b are provided at positions in an opposite direction to the X direction. In the example illustrated in FIG. 3, two electrodes 33b are arranged side by side in the Y direction, but the two electrodes 33b are connected in the inside of the transistor 30b. Note that the arrangement of the electrodes 33b is not limited to the configuration and arrangement illustrated in FIG. 3. For example, the electrodes 33b may be a single electrode having a rectangular shape extending in the Y direction. The electrodes 33b function as a gate terminal of the transistor 30b.

The light receiving element 40 is provided on the lower surfaces of the transistors 30a and 30b via the adhesive layers 62a and 62b, in such a manner as to extend across the transistors 30a and 30b in a long-side direction (Y direction). The light receiving element 40 is provided at such a position as not to overlap the electrodes 32a and 33a of the transistor 30a and the electrodes 32b and 33b of the transistor 30b in the Z direction. In the example illustrated in FIG. 3, the light receiving element 40 is provided at an X-directional position, as viewed from the electrodes 32a, 32b, 33a and 33b.

Short sides of an adhesion surface with the transistors 30a and 30b in the light receiving element 40 are not provided on the lower surface of each of the transistors 30a and 30b. In other words, vertices of the adhesion surface with the transistors 30a and 30b in the rectangular shaped light receiving element 40 are provided at positions that do not overlap each of the transistors 30a and 30b in the Z direction.

The light receiving element 40 includes electrodes 41 and 42. The electrodes 41 and 42 are provided on a lower surface of the light receiving element 40. The electrodes 41 and 42 are provided at positions that do not overlap a light receiving surface of the light receiving element 40. In the example illustrated in FIG. 3, the electrodes 41 and 42 are provided side by side in the Y direction. The electrode 41 functions as an anode terminal of the light receiving element 40. The electrode 42 functions as a cathode terminal of the light receiving element 40.

As illustrated in part (B) of FIG. 3, the lead frames 10a and 10b include first portions 10a-1 and 10b-1 that extend to the outside of the first resin member 80 and include end portions functioning as the input terminals 11a and 11b; second portions 10a-2 and 10b-2 extending in the Y direction; and third portions 10a-3 and 10b-3 extending in the X direction and connecting the respective first portions and second portions. The first portion 10a-1 of the lead frame 10a and the first portion 10b-1 of the lead frame 10b are provided side by side in the Y direction. The second portion 10a-2 of the lead frame 10a and the second portion 10b-2 of the lead frame 10b are arranged side by side in the X direction, and the second portion 10b-2 of the lead frame 10b is provided further toward the side on which the first portions 10a-1 and 10b-1 of the lead frames 10a and 10b are provided, than the second portion 10a-2 of the lead frame 10a. The length of the short side of the second portion 10a-2 of the lead frame 10a is greater than the length of the short side of the second portion 10b-2 of the lead frame 10b, and is sufficiently greater than the length of the short side of the light emitting element 50. The third portion 10a-3 of the lead frame 10a and the third portion 10b-3 of the lead frame 10b are arranged side by side in such a manner that the second portions 10a-2 and 10b-2 of the lead frames 10a and 10b are interposed in the Y direction.

The light emitting element 50 is provided on an upper surface of the second portion 10a-2 of the lead frame 10a via the adhesive layer 63. The light emitting element 50 includes electrodes 51 and 52. The electrode 51 is provided on a lower surface of the light emitting element 50, and is in contact with the adhesive layer 63. The electrode 52 is provided on an upper surface of the light emitting element 50. The electrode 52 is provided at a position that does not overlap a light emitting surface of the light emitting element 50. The electrode 51 functions as an anode terminal of the light emitting element 50. The electrode 52 functions as a cathode terminal of the light emitting element 50.

The adhesive layer 61a is formed of a connecting member having electrical conductivity, and includes, for example, silver paste. The adhesive layer 61a adheres and fixes the lower surface of the second portion 20a-2 of the lead frame 20a to the upper surface of the transistor 30a. The adhesive layer 61a electrically connects the electrode 31a of the transistor 30a and the lead frame 20a.

The adhesive layer 61b is formed of a connecting member having electrical conductivity, and includes, for example, silver paste. The adhesive layer 61b adheres and fixes the lower surface of the second portion 20b-2 of the lead frame 20b to the upper surface of the transistor 30b. The adhesive layer 61b electrically connects the electrode 31b of the transistor 30b and the lead frame 20b.

The adhesive layer 62a is formed of a connecting member having electrical insulation. The adhesive layer 62a adheres and fixes the lower surface of the transistor 30a to the upper surface of the light receiving element 40. Note that the adhesive layer 62a may have electrical conductivity.

The adhesive layer 62b is formed of a connecting member having electrical insulation. The adhesive layer 62b adheres and fixes the lower surface of the transistor 30b to the upper surface of the light receiving element 40. Note that the adhesive layer 62b may have electrical conductivity.

The adhesive layer 63 is formed of a connecting member having electrical conductivity, and includes, for example, silver paste. The adhesive layer 63 adheres and fixes the upper surface of the second portion 10a-2 of the lead frame 10a to the lower surface of the light emitting element 50. The adhesive layer 63 electrically connects the electrode 51 of the light emitting element 50 and the lead frame 10a.

The wires 70, 71, 72, 73 and 74 are, for example, bonding wires. The wires 70, 71, 72, 73 and 74 include, for example, copper or gold. The wire 70 connects the electrode 32a of the transistor 30a and the electrode 32b of the transistor 30b. The wire 71 connects the electrode 33a of the transistor 30a and the electrode 33b of the transistor 30b. The wire 72 connects the electrode 33a of the transistor 30a and the electrode 41 of the light receiving element 40. The wire 73 connects the electrode 32b of the transistor 30b and the electrode 42 of the light receiving element 40. The wire 74 electrically connects the electrode 52 of the light emitting element 50 and the lead frame 10b. Note that the wire 72 may connect the electrode 33b of the transistor 30b and the electrode 41 of the light receiving element 40, and the wire 73 may connect the electrode 32a of the transistor 30a and the electrode 42 of the light receiving element 40.

The wires 72 and 73 are provided in such a manner as to cross neither the wire 70 nor wire 71 in plan view. Thereby, the height in the Z direction of the wires 72 and 73 can be reduced, and the distance in the Z direction between the light receiving element 40 and the light emitting element 50 can be shortened. Accordingly, the height in the Z direction of the photo relay device 1 can be reduced, and the device can be reduced in size. However, the arrangement of the wires is merely an example in connection with the structure and advantageous effects in the first embodiment, and the wires may intersect, and the advantageous effects of the first embodiment are not lost by the intersecting of the wires.
1.3. Cross-Sectional Structure

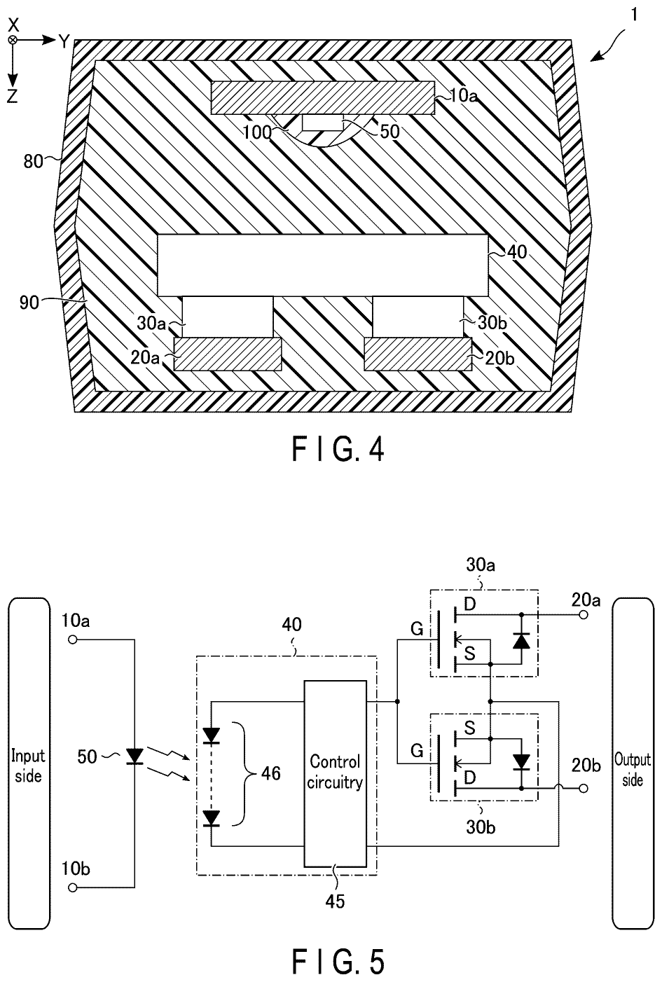

A cross-sectional structure of the photo relay device according to the first embodiment is illustrated by using FIG. 2 and FIG. 4. FIG. 4 is a cross-sectional view along line IV-IV in FIG. 3, illustrating an example of a cross-sectional structure of the photo relay device according to the first embodiment. Note that in FIG. 4, the depiction of the adhesive layers 61a, 61b, 62a, 62b and 63 and the wires CW is omitted.

The lead frames 20a and 20b are provided such that surfaces in −Z direction (upper surfaces on the drawing sheet) thereof form a substantially identical plane. In addition, the transistors 30a and 30b are provided such that surfaces in −Z direction (upper surfaces on the drawing sheet) thereof form a substantially identical plane.

As illustrated in FIG. 4, the light receiving element 40 includes a portion sandwiched between the transistor 30a and the second resin member 90 in the Z direction, a portion sandwiched between the transistor 30b and the second resin member 90 in the Z direction, and a portion sandwiched by the second resin member 90 on both surfaces thereof in the Z direction. Specifically, the surface in the −Z direction (the upper surface on the drawing sheet) of the light receiving element 40 is uniformly in contact with the second resin member 90. At this time, the light receiving element 40 and the second resin member 90 are put in close contact. In addition, the surface in the Z direction (the lower surface on the drawing sheet) of the light receiving element 40 is, successively in the Y direction, put in contact with second resin member 90; the transistor 30a via the adhesive layer 62a; the second resin member 90; the transistor 30b via the adhesive layer 62b; and the second resin member 90.

As illustrated in FIG. 2 and FIG. 4, the light emitting element 50 is provided at a position overlapping with the light receiving element 40 in the Z direction. By this structure, in a case where light radiated from the light emitting element 50 is received by the light receiving element 40, the loss of light can be suppressed, and the reliability of the photo relay device 1 can be enhanced.
1.4. Circuit Configuration

A circuit configuration of the photo relay device according to the first embodiment is illustrated by using FIG. 5. FIG. 5 is a circuit diagram illustrating an example of a circuit configuration of the photo relay device according to the first embodiment.

The transistors 30a and 30b are used for the control of a signal to be transmitted. The drain terminals of the transistors 30a and 30b are connected to the lead frames 20a and 20b, respectively. The source terminals of the transistors 30a and 30b are commonly connected to the cathode of the light receiving element 40. The gate terminals of the transistors 30a and 30b are commonly connected to the anode of the light receiving element 40.

The light receiving element 40 is, for example, a PDA including control circuitry 45 and several to ten-odd photodiodes 46 that are connected in series. Both ends of the series-connected photodiodes 46 are connected to the control circuitry 45. The control circuitry 45 controls the transistors 30a and 30b by using a voltage applied from the photodiodes 46 as a power supply voltage.

The light emitting element 50 includes the anode connected to the lead frame 10a, and the cathode connected to the lead frame 10b. Signals that are transmitted through the photo relay device 1 are input to the lead frames 10a and 10b.

If a sufficient potential difference occurs between the lead frames 10a and 10b, the light emitting element 50 enters an ON state (light emission state). At this time, the light receiving element 40 receives light from the light emitting element 50, and causes voltage to occur between the anode and the cathode. Thereby, the transistors 30a and 30b enter an ON stage, and the lead frames 20a and 20b are mutually connected. On the other hand, if the potential difference between the lead frames 10a and 10b decreases and the light emitting element 50 enters an OFF state (light extinction state), the transistors 30a and 30b enter an OFF state and the lead frames 20a and 20b are insulated from each other.
1.5. Advantageous Effects

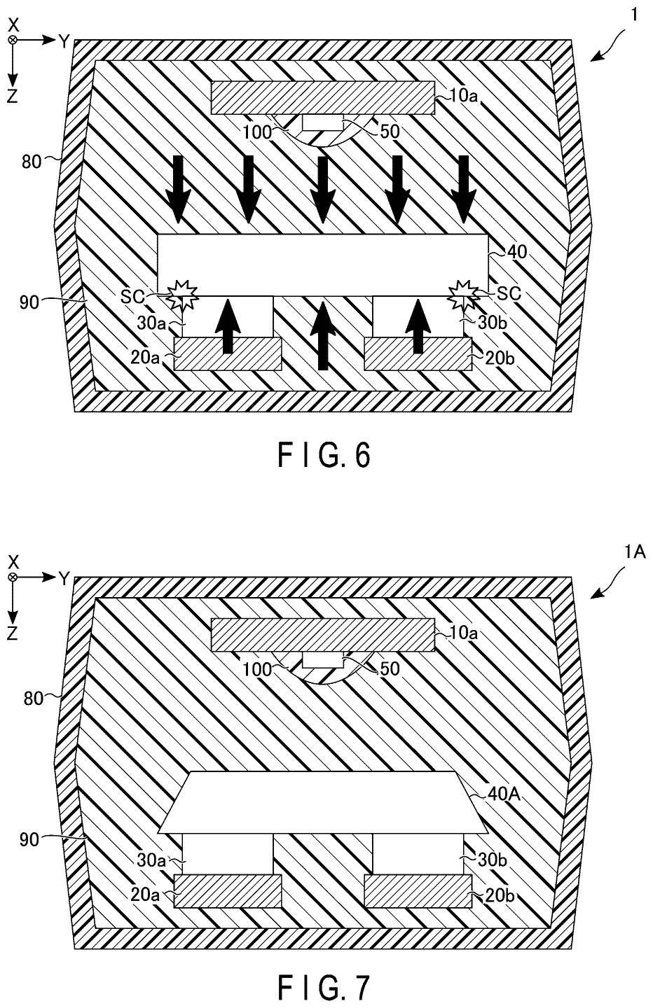

The photo relay device according to the first embodiment can reduce the stress influence on semiconductor elements. This advantageous effect is described with reference to FIG. 6. FIG. 6 is a diagram illustrating a stress influence in the photo relay device according to the first embodiment. In FIG. 6, directions of stress that the light receiving element 40 receives are indicated by arrows on the cross-sectional structure of the photo relay device illustrated in FIG. 4. Note that the magnitude and length of the arrow have no relation to the magnitude of stress.

In the photo relay device 1 according to the first embodiment, as illustrated in FIG. 6, the light receiving element 40 receives stress from the transistors 30a and 30b and the second resin member 90. For example, all stress that the light receiving element 40 receives is compression stress. This aims at suppressing a decrease in reliability due to a phenomenon that a gap occurs by peeling of the second resin member 90 from the light receiving element 40 and each semiconductor element, and light radiated from the light emitting element 50 is lost by multiple reflection in the gap. At this time, since a surface in the −Z direction (an upper surface on the drawing sheet) of the light receiving element 40 is substantially uniformly put in contact with the second resin member 90, the light receiving element 40 receives compression of a substantially uniform magnitude from the second resin member 90. On the other hand, a surface in the Z direction (a lower surface on the drawing sheet) of the light receiving element 40 includes a part being in contact with the transistors 30a and 30b and a part being in contact with the second resin member 90. Since the magnitudes of stress that the light receiving element 40 receives from the members of different materials are different, the stress distribution becomes nonuniform. Here, if attention is paid to the stress between the light receiving element 40 and the transistors 30a and 30b, a location where stress concentrates occurs at a part of the adhesion surface therebetween. If stress concentrates at a part, there is a possibility that an influence different from a normal state is exerted on the operations of the semiconductor elements and the photo relay device 1 in which the semiconductor elements are used, such as destruction of the circuitry provided on the surface of the transistors 30a and 30b, and the light receiving element 40.

In the photo relay device according to the first embodiment, the light receiving element 40 is provided on the two transistors 30a and 30b in such a manner as to extend across the transistors 30a and 30b. In addition, the vertices of the adhesion surface with the transistors 30a and 30b in the light receiving element 40 are provided at positions that do not overlap the transistors 30a and 30b in the Z direction. By this structure, the stress between the light receiving element 40 and the transistors 30a and 30b concentrates, for example, at stress concentration parts SC illustrated in FIG. 6. The stress concentration parts SC occur, for example, on line segments at which sides of the adhesion surface with the light receiving element 40 in the transistors 30a and 30b intersect with the adhesion surface with the transistors 30a and 30b in the light receiving element 40.

The stress concentration parts SC illustrated in FIG. 6 correspond to the bottom surface of the light receiving element 40. In general, a substrate is present on the bottom surface of the light receiving element, and the bottom surface is less affected by stress. In addition, it is rare that circuitry is provided on the bottom surface of the light receiving element. Besides, in a case where circuitry is provided on a surface of the semiconductor element, such circuitry, in general, is provided in such a manner as to avoid edge portions of the surface because of restrictions at the time of manufacture. Thus, in the transistors 30a and 30b, circuitry is not provided on the surface on which the stress concentration part SC are present. From the above, the photo relay device 1 is less affected by the influence of circuitry destruction due to stress concentration.

From the above, the photo relay device 1 according to the first embodiment can control the stress influence between the semiconductor elements by changing the structure, without changing the material or the like of the resin member. As a result, the risk of a fault of the photo relay device 1 due to the stress applied to the semiconductor elements can be reduced. Note that since the occurrence of stress is also due to a physical constant peculiar to resin, the risk of a fault due to temperature variations can be reduced by considering and reflecting nonuniformity in stress due to contraction at low temperatures and expansion at high temperatures. In other words, also in regard to the stress occurring due to temperature variations, the advantageous effects of the first embodiment can be obtained.

### 2. Second Embodiment

Next, a second embodiment is described. Hereinafter, a different structure from the first embodiment is mainly described.
2.1. Cross-Sectional Structure

FIG. 7 is a cross-sectional view illustrating an example of an internal structure of a photo relay device according to the second embodiment. The cross section illustrated in FIG. 7 corresponds to the cross section illustrated in FIG. 4 in the first embodiment.

A photo relay device 1A according to the second

embodiment includes a light receiving element 40A in place of the light receiving element 40. As illustrated in FIG. 7, a YZ cross section of the light receiving element 40A has such an isosceles trapezoid shape that the adhesion surface side with the transistors 30a and 30b becomes a longer base of two bases. Specifically, a Y-directional side portion of the light receiving element 40A has an inclination with respect to the Z direction. In addition, although not illustrated, an XZ cross section of the light receiving element 40A similarly has such an isosceles trapezoid shape that the adhesion surface side with the transistors 30a and 30b becomes a longer base of two bases. Specifically, an X-directional side portion of the light receiving element 40A has an inclination with respect to the Z direction. In short, the light receiving element 40A has such a truncated quadrangular pyramid shape that the adhesion surface side with the transistors 30a and 30b becomes a bottom surface having a large area.

The short sides of the adhesion surface with the transistors 30a and 30b in the light receiving element 40A are not provided on the lower surface of each of the transistors 30a and 30b. In other words, the vertices of the Z-directional surface (the lower surface on the drawing sheet) that is the adhesion surface with the transistors 30a and 30b in the light receiving element 40A are provided at positions that do not overlap the transistors 30a and 30b in the Z direction. Note that the vertices of the-Z-directional surface (the upper surface on the drawing sheet) of the light receiving element 40A may be provided at positions that overlap the transistor 30a or 30b in the Z direction.
2.2. Manufacturing Method

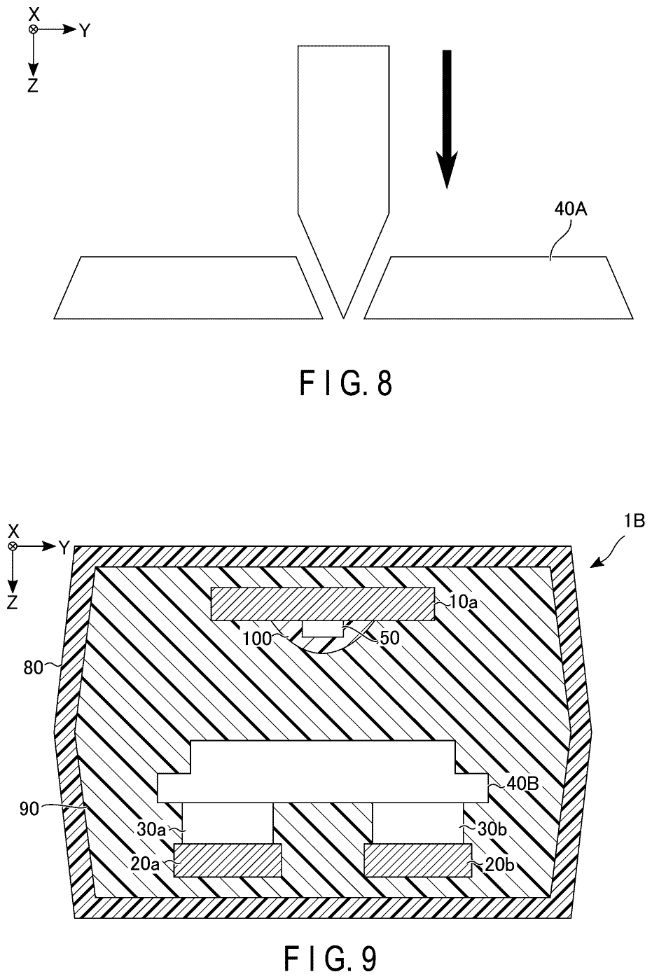

A manufacturing method of the light receiving element 40A according to the second embodiment is described with reference to FIG. 8. FIG. 8 is a diagram illustrating an example of a dicing step of the light receiving element in the process of manufacturing the photo relay device according to the second embodiment.

The light receiving element 40A can be manufactured by singulating, in a dicing step, a plurality of light receiving elements 40A formed by being arranged in the X direction and Y direction on a single wafer. In the dicing step at the time of manufacturing the light receiving element 40A according to the second embodiment, a dicing saw including a tapered blade as illustrated in FIG. 8 is used. By using the dicing saw including the tapered blade, the cross section is inclined in such a manner as to extend along the taper of the blade. By the above, the light receiving element 40A having the truncated quadrangular pyramid shape is manufactured.
2.3. Advantageous Effects

Like the first embodiment, the photo relay device 1A according to the second embodiment can reduce the stress influence on semiconductor elements. In addition, by forming the light receiving element 40A in the truncated quadrangular pyramid shape, the distribution of the stress that the light receiving element 40A receives varies, and thus the stress tends to be easily distributed, and the risk of stress concentration, which leads to a fault of the photo relay device 1A, such as destruction of circuitry provided on the surface, is reduced.
2.4. Modifications

The photo relay device 1A according to the second embodiment can variously be modified.

For example, the light receiving element 40A may have a shape of an isosceles trapezoidal pillar, such that one of the YZ cross section and the XZ cross section has an isosceles trapezoid shape, and the other has a rectangular shape. In this case, the light receiving element 40A is manufactured by using, in the dicing step, a dicing saw including a tapered blade at a time of dividing in the direction for the isosceles trapezoid shape, and by using a dicing saw including a rectangular blade at a time of dividing in the direction for the rectangular shape.

In addition, in a case where the stress direction is different depending on the structure and disposition of the photo relay device 1A, the light receiving element 40A may have such an inverted truncated quadrangular pyramid shape that the bottom area on the adhesion surface side with the transistors 30a and 30b is smaller. This shape is advantageous in that the stress applied to the light receiving element 40A is distributed, for example, in a case where another semiconductor element is further provided on the −Z surface of the light receiving element 40A and the direction of stress that the light receiving element 40A receives from the second resin member 90 becomes a reverse direction. The light receiving element 40A of the inverted truncated quadrangular pyramid shape is manufactured by dicing a plurality of light receiving elements 40A formed on a wafer, by using a tapered dicing saw from the back-surface side.

### 3. Third Embodiment

Next, a third embodiment is described. Hereinafter, a different structure from the first embodiment mainly described.
3.1. Cross-Sectional Structure

FIG. 9 is a cross-sectional view illustrating an example of an internal structure of a photo relay device according to the third embodiment. The cross section illustrated in FIG. 9 corresponds to the cross section illustrated in FIG. 4 in the first embodiment.

A photo relay device 1B according to the third embodiment includes a light receiving element 40B in place of the light receiving element 40. As illustrated in FIG. 9, the light receiving element 40B includes steps in the Z direction in Y-directional side portions, and has a YZ cross section of a projecting shape. In addition, although not illustrated, the light receiving element 40B similarly includes steps in the Z direction in X-directional side portions, and has an XZ cross section of a projecting shape. In other words, the light receiving element 40B has a step pyramid shape. Note that in the example of FIG. 9, two steps are provided in each of the Y-directional side portions in the YZ cross section, but the embodiment is not limited to this. For example, three or more steps may be provided in each of the Y-directional side portions in the YZ cross section. The same applies to the X-directional side portions in the XZ cross section.

Short sides of an adhesion surface with the transistors 30a and 30b in the light receiving element 40B are not provided on the lower surface of each of the transistors 30a and 30b. In other words, the vertices of the Z-directional surface (the lower surface on the drawing sheet) that is the adhesion surface with the transistors 30a and 30b in the light receiving element 40B are provided at positions that do not overlap each of the transistors 30a and 30b in the Z direction. Note that the vertices of the −Z-directional surface (the upper surface on the drawing sheet) of the light receiving element 40B may be provided at positions that overlap the transistor 30a or 30b in the Z direction.
3.2. Manufacturing Method

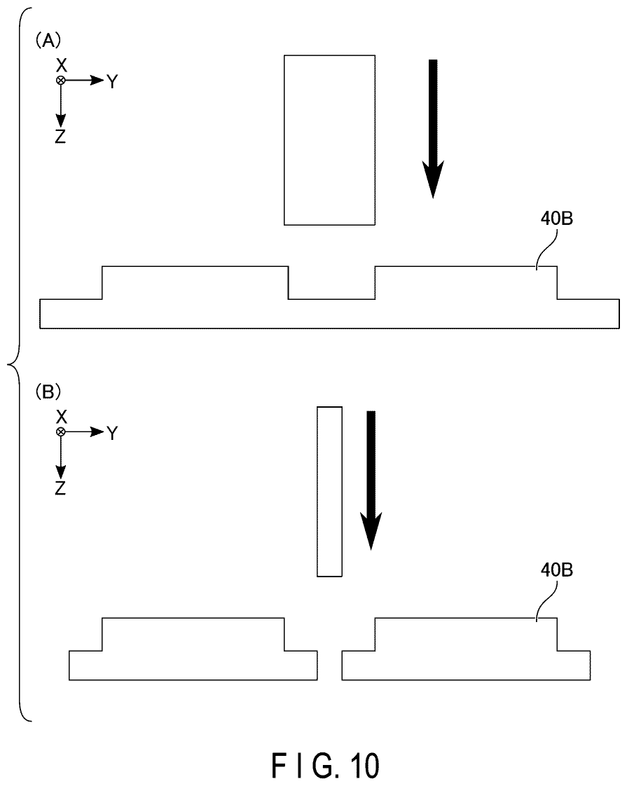

A manufacturing method of the light receiving element 40B according to the third embodiment is described with reference to FIG. 10. FIG. 10 is a diagram illustrating an example of a dicing step of the light receiving element in the process of manufacturing the photo relay device according to the third embodiment. Hereinafter, a case is described in which the light receiving element 40B has a step pyramid shape including two steps in each of the X-directional side portions and the Y-directional side portions.

The light receiving element 40B can be manufactured by singulating, in a dicing step, a plurality of light receiving elements 40B formed by being arranged in the X direction and Y direction on a single wafer. The dicing step at the time of manufacturing the light receiving element 40B according to the third embodiment is performed in two stages. In the first stage, as illustrated in part (A) of FIG. 10, half dicing is performed in which dicing is performed down to an intermediate point in the thickness direction of the wafer, by using a dicing saw having a relatively large width. Then, in the second stage, as illustrated in part (B) of FIG. 10, by using a dicing saw having a relatively small width, compared to the first stage, dicing is performed to completely divide a central portion of the part where the half dicing was performed in the first stage. By the above step, steps are formed in the side portions in the cross section. The width of the step portion can freely be adjusted by changing the widths of the blades of the dicing saws used in the first stage and second stage. By the above, the light receiving element 40B having the step pyramid shape can be manufactured.

Note that in the case where the light receiving element 40B has a step pyramid shape with three or more steps, dicing is performed in stages corresponding to the number of steps.
3.3. Advantageous Effects

Like the first embodiment, the photo relay device 1B according to the third embodiment can reduce the stress influence on semiconductor elements. In addition, by forming the light receiving element 40B in the step pyramid shape, the distribution of the stress that the light receiving element 40B receives varies, and thus the stress tends to be easily distributed, and the risk of stress concentration, which leads to a fault of the photo relay device 1B, such as destruction of circuitry provided on the surface, is reduced.
3.4. Modification

The photo relay device 1B according to the third embodiment can variously be modified.

For example, the light receiving element 40B may have such a shape that one of the XZ cross section and the YZ cross section includes a step in a side portion, and the other has a rectangular shape without a step. In this case, the light receiving element 40B is manufactured by performing, in the dicing step, the above-described multiple-stage dicing in a case of dividing in the direction in which the step is included, and by performing dicing at a time in a case of dividing in the direction in which the rectangular shape is formed.

In addition, in a case where the stress direction is different depending on the structure and disposition of the photo relay device 1B, the light receiving element 40B may have an inverted step pyramid shape in which such steps as to rise toward the adhesion surface side with the transistors 30a and 30b are provided. This shape is advantageous in that the stress applied to the light receiving element 40B is distributed, for example, in a case where another semiconductor element is further provided on the-Z surface of the light receiving element 40B and the direction of stress that the light receiving element 40B receives from the second resin member 90 becomes a reverse direction. The light receiving element 40B of this inverted step pyramid shape is manufactured by dicing a plurality of light receiving elements 40B formed on a wafer, by performing two-stage dicing from the back-surface side.

### 4. Others

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
a first transistor;
a light receiving element that is in contact with the first transistor in a first direction, with a light receiving surface of the light receiving element being provided to face in the first direction;
a light emitting element including a radiation surface that is provided to face the light receiving surface of the light receiving element in the first direction; and
a first resin member that seals the first transistor, the light receiving element and the light emitting element, and has light transmissivity, wherein
a vertex of a surface that is in contact with the first transistor in the light receiving element is provided at a position that does not overlap the first transistor in the first direction.

2. The semiconductor device of claim 1, wherein the light receiving element is provided such that an area of a surface thereof that is in contact with the first transistor is different from an area of a surface thereof on which the light receiving surface is provided.

3. The semiconductor device of claim 2, wherein a side portion of the light receiving element includes an inclined surface that is inclined with respect to the first direction.

4. The semiconductor device of claim 3, wherein the light receiving element has such a truncated quadrangular pyramid shape that the area of the surface that is in contact with the first transistor is greater than the area of the surface on which the light receiving surface is provided.

5. The semiconductor device of claim 3, wherein the light receiving element has such a truncated quadrangular pyramid shape that the area of the surface on which the light receiving surface is provided is greater than the area of the surface that is in contact with the first transistor.

6. The semiconductor device of claim 2, wherein a side portion of the light receiving element includes a step in the first direction.

7. The semiconductor device of claim 6, wherein the light receiving element has such a step pyramid shape that the area of the surface that is in contact with the first transistor is greater than the area of the surface on which the light receiving surface is provided.

8. The semiconductor device of claim 6, wherein the light receiving element has such a step pyramid shape that the area of the surface on which the light receiving surface is provided is greater than the area of the surface that is in contact with the first transistor.

9. The semiconductor device of claim 1, further comprising a first lead frame and a second lead frame, wherein
the light emitting element is provided in such a manner as to be in contact with the first lead frame in the first direction, and
the first transistor is provided in such a manner as to be in contact with the second lead frame in the first direction.

10. The semiconductor device of claim 9, further comprising:
a second resin member that seals the light emitting element on the first lead frame and has light transmissivity, the first resin member sealing the light emitting element via the second resin member; and
a third resin member that seals the first resin member, the first lead frame and the second lead frame and has a light shielding property, wherein
each of the first lead frame and the second lead frame includes a connection portion extending from the third resin member.

11. The semiconductor device of claim 1, further comprising a second transistor provided side by side with the first transistor in a second direction perpendicular to the first direction, wherein
the light receiving element is further in contact with the second transistor in the first direction, and is provided in such a manner as to extend across the first transistor and the second transistor in the second direction,
a vertex of a surface that is in contact with the second transistor in the light receiving element is provided at a position that does not overlap the second transistor in the first direction, and
the first resin member further seals the second transistor.

12. The semiconductor device of claim 11, further comprising a first lead frame, a second lead frame and a third lead frame, wherein
the light emitting element is provided in such a manner as to be in contact with the first lead frame in the first direction,
the first transistor is provided in such a manner as to be in contact with the second lead frame in the first direction, and
the second transistor is provided in such a manner as to be in contact with the third lead frame in the first direction.

13. The semiconductor device of claim 12, further comprising:
a second resin member that seals the light emitting element on the first lead frame and has light transmissivity, the first resin member sealing the light emitting element via the second resin member; and
a third resin member that seals the first resin member, the first lead frame, the second lead frame and the third lead frame and has a light shielding property, wherein
each of the first lead frame, the second lead frame and the third lead frame includes a connection portion extending from the third resin member.

14. The semiconductor device of claim 12, further comprising a fourth lead frame, wherein
one terminal of the light emitting element is connected to the first lead frame, and the other terminal of the light emitting element is connected to the fourth lead frame,
one terminal of the light receiving element is commonly connected to a gate terminal of the first transistor and to a gate terminal of the second transistor, and the other terminal of the light receiving element is commonly connected to a source terminal of the first transistor and to a source terminal of the second transistor,
a drain terminal of the first transistor is connected to the second lead frame, and
a drain terminal of the second transistor is connected to the third lead frame.

15. The semiconductor device of claim 14, further comprising:
a second resin member that seals the light emitting element on the first lead frame and has light transmissivity, the first resin member sealing the light emitting element via the second resin member; and
a third resin member that seals the first resin member, the first lead frame, the second lead frame, the third lead frame and the fourth lead frame and has a light shielding property, wherein
each of the first lead frame, the second lead frame, the third lead frame and the fourth lead frame includes a connection portion extending from the third resin member.

16. The semiconductor device of claim 15, wherein
the connection portion of the first lead frame and the connection portion of the fourth lead frame are arranged side by side in the second direction, and
the connection portion of the second lead frame and the connection portion of the third lead frame are arranged side by side in the second direction.

17. The semiconductor device of claim 16, wherein
the connection portion of the first lead frame and the connection portion of the fourth lead frame extend from the third resin member in a third direction crossing the first direction and the second direction, and
the connection portion of the second lead frame and the connection portion of the third lead frame extend from the third resin member in an opposite direction to the third direction.
